(19) United States
(12) Patent Application Publication
(10) Pub. No.: US 2024/0170259 A1
(43) Pub. Date: May 23, 2024

(54) PLASMA PROCESSING APPARATUS

(71) Applicant: Tokyo Electron Limited, Tokyo (JP)

(72) Inventors: Hiroshi KONDO, Tokyo (JP); Eiki KAMATA, Yamanashi (JP)

(21) Appl. No.: 18/510,273

(22) Filed: Nov. 15, 2023

(30) Foreign Application Priority Data
Nov. 18, 2022 (JP) 2022-184635

(51) Int. Cl. H01J 37/32

(52) U.S. Cl. CPC H01J 37/32211; H01J 37/32266

(57) ABSTRACT

A plasma processing apparatus includes a chamber, a microwave source, and a distributor. The chamber is configured to place a substrate therein and includes a plurality of radiation units that radiate microwaves, which are arranged while facing the substrate. The microwave source outputs microwaves. The distributor has one end connected to the microwave source, and the other end branched and connected to the plurality of radiation units, and distributes and transmits the microwaves output from the microwave source to the plurality of radiation units, in which when a wavelength of the microwaves is λ, a line length from the one end to the other end falls within a predetermined range beginning from n×λ/2 (n is a natural number).

### CROSS-REFERENCE TO RELATED APPLICATIONS

This application is based on and claims priority from Japanese Patent Application No. 2022-184635, filed on Nov. 18, 2022, with the Japan Patent Office, the disclosure of which is incorporated herein in its entirety by reference.

### TECHNICAL FIELD

The present disclosure relates to a plasma processing apparatus.

### BACKGROUND

Japanese Patent Laid-Open No. 2012-216745 discloses a plasma processing apparatus that includes: a processing container that accommodates a processing target; a stage disposed inside the processing container and having a placement surface on which the processing target is placed; a gas supply mechanism that supplies a processing gas into the processing container; and a microwave introduction device that generates microwaves for forming plasma of the processing gas within the processing container and introduces the microwaves into the processing container. The microwave introduction device includes: a conductive member disposed above the processing container and having a plurality of openings; and a plurality of microwave transmission windows which are fitted into the plurality of openings. The microwaves pass through the microwave transmission windows and are introduced into the processing container. The microwave transmission windows are disposed on one virtual plane parallel to the placement surface while being fitted into the openings, and include a first microwave transmission window, and second and third microwave transmission windows adjacent to the first microwave transmission window. The first to third microwave transmission windows are disposed such that a distance between the center point of the first microwave transmission window and the center point of the second microwave transmission window, and a distance between the center point of the first microwave transmission window and the center point of the third microwave transmission window are set to be equal or approximately equal to each other.

### SUMMARY

According to an aspect of the present disclosure, a plasma processing apparatus includes a chamber, a microwave source, and a distributor. The chamber is configured to place a substrate therein, and includes a plurality of radiation units that radiate microwaves, which are arranged while facing the substrate. The microwave source outputs microwaves. The distributor has one end connected to the microwave source, and the other end branched and connected to the plurality of radiation units, and distributes and transmits the microwaves output from the microwave source to the plurality of radiation units, in which when a wavelength of the microwaves is λ, a line length from the one end to the other end falls within a predetermined range beginning from n×λ/2 (n is a natural number).

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view schematically illustrating an example of a plasma processing apparatus according to a first embodiment.

FIG. 2 is a view schematically illustrating an example of the configuration of a microwave introduction device according to the first embodiment.

FIG. 3 is a view schematically illustrating an example of a microwave radiation mechanism according to the first embodiment.

FIG. 4 is a top view illustrating an example of a schematic configuration of a ceiling wall of a processing container according to the first embodiment.

FIG. 5 is a view illustrating the connection relationship between microwave transmission modules and radiation units according to the first embodiment.

FIG. 6 is a view illustrating a schematic configuration of a distributor according to the first embodiment.

FIG. 7 is a view illustrating the characteristic impedance of the distribution unit 170 according to the first embodiment.

FIG. 8 is a smith chart illustrating the impedance matching states.

FIG. 9 is a top view illustrating an example of a schematic configuration of a ceiling wall of a processing container according to a second embodiment.

FIG. 10 is a view illustrating the connection relationship between microwave transmission modules and radiation units according to the second embodiment.

FIG. 11 is a view illustrating a schematic configuration of a distributor according to the second embodiment.

FIG. 12 is a view illustrating an example of the distributor having a ring-shaped transmission line according to the second embodiment.

FIG. 13 is a view illustrating an example of the distributor having the ring-shaped transmission line according to the second embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of a plasma processing apparatus will be described in detail with reference to drawings. The disclosed plasma processing apparatus is not limited by the following embodiments.

In the related art, there has been a plasma processing apparatus in which radiation units that radiate microwaves are provided at a plurality of places of a chamber, and microwaves are radiated into the chamber from the radiation units to form plasma. In such a plasma processing apparatus, when microwave sources are provided for the radiation units, respectively, the number of microwave sources increases, resulting in an increase in cost. Therefore, a configuration may be considered in which microwaves are distributed from one microwave source to two or more radiation units.

However, when microwaves are distributed from a microwave source to two or more radiation units, the transmission line becomes longer due to a distributor that distributes the microwaves. For short-wavelength electromagnetic waves such as microwaves, in some cases, the length of the transmission line in the portion of the distributor that distributes the microwaves may also affect the impedance, thereby affecting impedance matching. For example, in some cases, impedance matching between the input side and the output side may not be achieved, and then reflection or loss of microwaves may occur. Therefore, there are expectations for a technique that may distribute microwaves while suppressing the influence of the portion of the distributor on the impedance.

### First Embodiment

### Apparatus Configuration

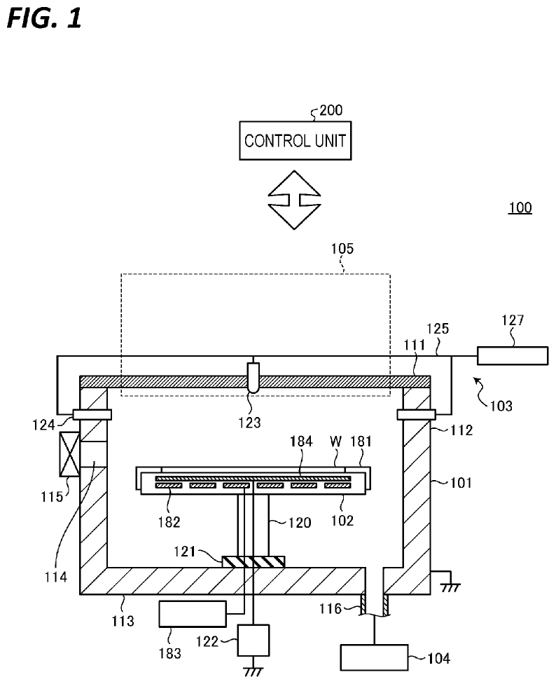

Hereinafter, an example of a plasma processing apparatus of the present disclosure will be described by using embodiments. First, a first embodiment will be described. FIG. 1 is a cross-sectional view schematically illustrating an example of a plasma processing apparatus 100 according to a first embodiment. The plasma processing apparatus 100 illustrated in FIG. 1 includes a processing container 101, a stage 102, a gas supply mechanism 103, an exhaust device 104, a microwave introduction device 105, and a control unit 200. In the embodiment, the plasma processing apparatus 100 corresponds to the plasma processing apparatus of the present disclosure.

The processing container 101 accommodates a substrate W such as a semiconductor wafer. The stage 102 is provided inside the processing container 101. The substrate W is placed on the stage 102. The gas supply mechanism 103 supplies various gases into the processing container 101. The exhaust device 104 exhausts gases within the processing container 101. The microwave introduction device 105 generates microwaves and outputs the generated microwaves. The control unit 200 controls the operation of each unit of the plasma processing apparatus 100. In the embodiment, the microwave introduction device 105 corresponds to a microwave source of the present disclosure.

The processing container 101 is made of, for example, a metal material such as aluminum or an alloy thereof, and is formed into a substantially cylindrical shape. The processing container 101 has a plate-shaped ceiling wall 111 and a bottom wall 113 and a side wall 112 connecting the ceiling wall 111 to the bottom wall 113. The inner wall of the processing container 101 is coated with, for example, yttria (Y₂O₃) so that a protective film is formed. The side wall 112 has a loading/unloading port 114 through which the substrate W is loaded or unloaded to/from a transfer chamber (not illustrated) adjacent to the processing container 101. The loading/unloading port 114 is opened/closed by a gate valve 115.

The stage 102 is formed into a disk shape. The stage 102 is made of a dielectric. For example, the stage 102 is made of aluminum whose surface is anodized or a ceramic material, for example, aluminum nitride (AlN). The substrate W is placed on the top surface of the stage 102. The substrate W is placed such that its center is aligned with the center position of the stage 102. The stage 102 is supported by a cylindrical support member 120, which is made of ceramic such as AlN and extends upwards from the center of the bottom wall 113 of the processing container 101, and a base member 121. A guide ring 181 for guiding the substrate W is provided at the outer edge of the stage 102. A lifting pin (not illustrated) for raising and lowering the substrate W is provided within the stage 102 such that the lifting pin may protrude and retract from the upper surface of the stage 102.

Further, a resistance heating-type heater 182 is embedded in the stage 102. When power is supplied to the heater 182 from a heater power source 183, the heater 182 heats the substrate W placed on the stage 102. A thermocouple (not illustrated) is inserted into the stage 102, and the heating temperature of the substrate W may be controlled on the basis of a signal from the thermocouple. Furthermore, an electrode 184 having substantially the same size as the substrate W is buried above the heater 182 in the stage 102. A DC power supply unit 122 is electrically connected to the electrode 184. The DC power supply unit 122 periodically applies a DC voltage to the electrode 184 in the stage 102. For example, the DC power supply unit 122 includes a DC power supply and a pulse unit. The DC voltage supplied by the DC power supply is turned ON/OFF by the pulse unit, so that the DC power supply unit 122 periodically applies the pulsed DC voltage to the electrode 184.

The gas supply mechanism 103 includes gas introduction nozzles 123 and 124, a gas supply pipe 125, and a gas supply unit 127. The gas introduction nozzle 123 is provided in the ceiling wall 111. In the first embodiment, the gas introduction nozzle 123 is provided at a position through which the central axis of the stage 102 passes. The center of the substrate W placed on the stage 102 is aligned with the center position of the stage 102. Thus, the gas introduction nozzle 123 is located above the center of the substrate W. The gas introduction nozzle 124 is provided in the side wall 112 of the processing container 101. The gas supply unit 127 is connected to the gas introduction nozzles 123 and 124 through the gas supply pipe 125. The gas supply unit 127 has supply sources of various gases. Further, the gas supply unit 127 includes opening/closing valves that start and stop the supply of various gases, or flow rate regulators that adjust the flow rates of gases. The gas supply unit 127 supplies various gases, such as a processing gas to be used for plasma processing. The arrangement of the gas introduction nozzles 123 and 124 is merely an example, and the present disclosure is not limited to this. For example, a plurality of gas introduction nozzles 123 may be provided so as to surround the center of the ceiling wall 111.

An opening is formed in the bottom wall 113, and the exhaust device 104 is provided through an exhaust pipe 116 connected to the opening. The exhaust device 104 includes a vacuum pump and a pressure control valve. The gas within the processing container 101 is exhausted through the exhaust pipe 116 by the vacuum pump of the exhaust device 104. The pressure inside the processing container 101 is controlled by the pressure control valve of the exhaust device 104.

The microwave introduction device 105 is provided above the processing container 101. The microwave introduction device 105 introduces electromagnetic waves (microwaves) into the processing container 101 so as to generate plasma.

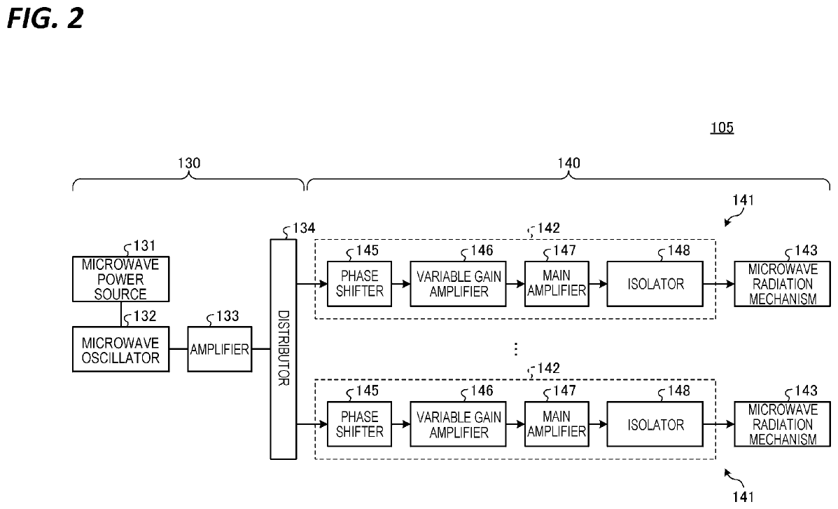

FIG. 2 is a view schematically illustrating an example of the configuration of the microwave introduction device 105 according to the first embodiment. The microwave introduction device 105 includes a microwave output unit 130 and a microwave radiation unit 140.

The microwave output unit 130 includes a microwave power source 131, a microwave oscillator 132, an amplifier 133, and a distributor 134. The microwave oscillator 132 is a solid state oscillator, and oscillates microwaves at, for example, 860 MHz (e.g., PLL oscillation). The frequency of microwaves is not limited to 860 MHZ, and those falling within a range of 700 MHz to 10 GHz, such as 2.45 GHZ, 8.35 GHz, 5.8 GHz, and 1.98 GHz, may be used. The amplifier 133 amplifies the microwaves oscillated by the microwave oscillator 132. The distributor 134 distributes the microwaves amplified by the amplifier 133 to a plurality of paths. The distributor 134 distributes the microwaves while matching the impedance on the input side to the impedance on the output side.

The microwave radiation unit 140 includes a plurality of microwave transmission modules 141. The microwaves distributed by the distributor 134 are input to each of the microwave transmission modules 141. The configurations of the microwave transmission modules 141 are all the same configurations. Each microwave transmission module 141 amplifies and radiates (outputs) the distributed microwaves. In the embodiment, the microwave transmission module 141 corresponds to a microwave transmitter of the present disclosure.

Each microwave transmission module 141 includes an amplification section 142 that mainly amplifies and outputs distributed microwaves, and a microwave radiation mechanism 143 that transmits the microwaves output from the amplification section 142 while performing matching with the load side impedance.

The amplification section 142 includes a phase shifter 145, a variable gain amplifier 146, a main amplifier 147, and an isolator 148. The phase shifter 145 changes the phase of microwaves to change the radiation characteristics of the microwaves. The variable gain amplifier 146 adjusts the power level of the microwaves to be input to the main amplifier 147. The main amplifier 147 is configured as a solid state amplifier. The isolator 148 separates the reflected microwaves which are reflected from the microwave radiation mechanism 143 side and are directed toward the main amplifier 147. When the radiation characteristics of the microwaves are not adjusted, the phase shifter 145 may not be provided.

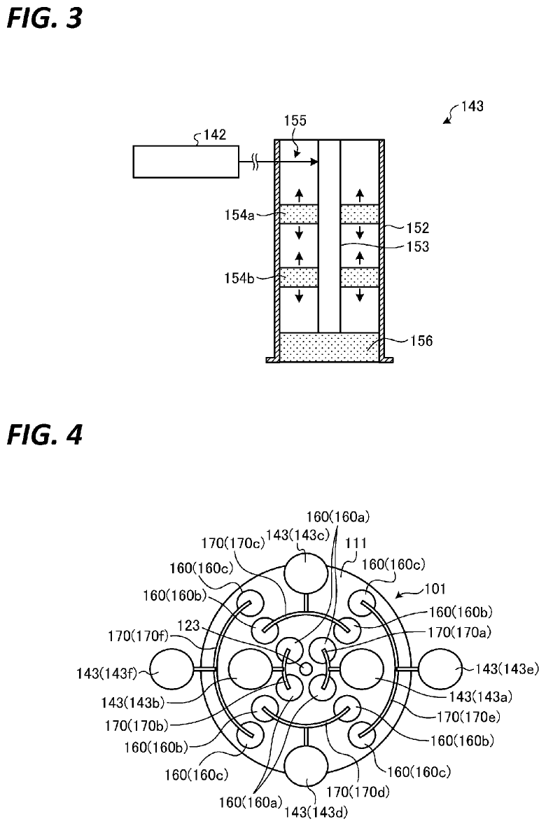

FIG. 3 is a view schematically illustrating an example of the microwave radiation mechanism 143 according to the first embodiment. The microwave radiation mechanism 143 is configured as a slug tuner. In the embodiment, the microwave radiation mechanism 143 corresponds to a matching unit of the present disclosure. The microwave radiation mechanism 143 has a cylindrical outer conductor 152 and a tubular inner conductor 153 coaxially provided within the outer conductor 152.

A space between the outer conductor 152 and the inner conductor 153 functions as a microwave transmission path. An impedance converter 156 is provided at one ends of the outer conductor 152 and the inner conductor 153. The impedance converter 156 is made of a dielectric. Examples of the dielectric may include quartz, ceramic such as alumina (Al₂O₃), and resins such as polytetrafluoroethylene and polyimide. Two slugs 154a and 154b are provided between the outer conductor 152 and the inner conductor 153. The slugs 154a and 154b are made of a dielectric material such as ceramic and are formed into plate-like ring shapes. The slugs 154a and 154b are disposed between the outer conductor 152 and the inner conductor 153 in a state where the inner conductor 153 passes through the respective central holes of the slugs 154a and 154b. Each of the slugs 154a and 154b is movable along the inner conductor 153 by a driving mechanism (not illustrated).

The microwave radiation mechanism 143 has a power feeding section 155. The power feeding section 155 is provided on the other end side of the outer conductor 152. The power feeding section 155 outputs the microwaves output from the amplification section 142, to the microwave transmission path. The microwave radiation mechanism 143 outputs the microwaves from the impedance converter 156, via the microwave transmission path. The microwave radiation mechanism 143 performs impedance matching between the input side and the output side by moving the two slugs 154a and 154b. The microwave radiation mechanism 143 may have another configuration as long as impedance matching may be performed.

FIG. 4 is a top view illustrating an example of a schematic configuration of the ceiling wall 111 of the processing container 101 according to the first embodiment. The ceiling wall 111 of the processing container 101 is formed into a disk shape. In the processing container 101, a plurality of radiation units 160 that radiate microwaves is disposed while facing the substrate W. For example, the gas introduction nozzle 123 is provided at the center position of the disk shape of the ceiling wall 111. The ceiling wall 111 is provided with the radiation units 160 which have different diameters from the center, are spaced apart from each other in the circumferential direction, and radiate microwaves. In the embodiment, the ceiling wall 111 is provided with radiation units 160a to 160c which have three diameters from the center side of the ceiling wall 111.

The radiation units 160a to 160c are disposed on concentric circles from the center of the ceiling wall 111, respectively. In the embodiment, four radiation units 160a, four radiation units 160b, and four radiation units 160c are arranged. The radiation units 160a (160b and 160c) are arranged at equal intervals in the circumferential direction on the circumference of each concentric circle. In the embodiment, the radiation units 160a (160b and 160c) are arranged at angular intervals of 90 degrees with respect to the center of the ceiling wall 111.

The plurality of microwave transmission modules 141 is provided in the microwave radiation unit 140. Each microwave transmission module 141 is connected to the radiation units 160 via each distribution unit 170. In the first embodiment, six microwave transmission modules 141 (141a to 141f) are provided in the microwave radiation unit 140. Each of the microwave transmission modules 141a to 141f is connected to two radiation units 160 via the distribution unit 170 (170a to 170f).

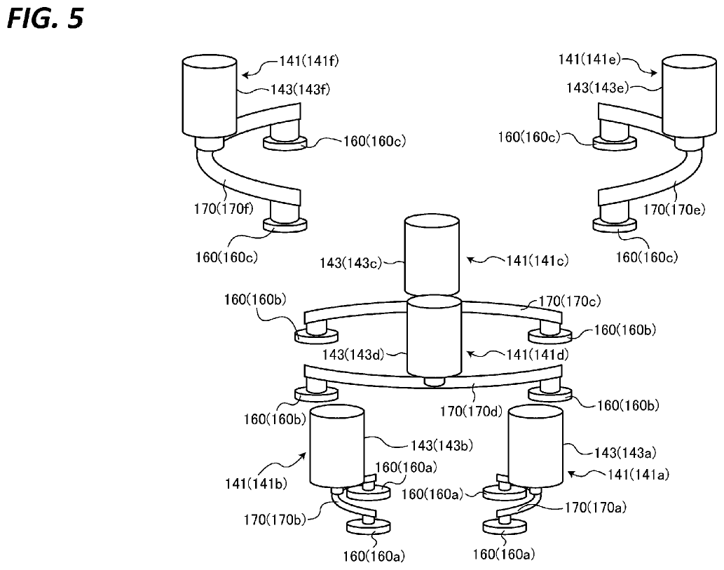

FIG. 4 and FIG. 5 described above illustrate the connection relationship between the microwave transmission modules 141a to 141f and the radiation units 160a to 160c. FIG. 5 is a view illustrating the connection relationship between the microwave transmission modules 141a to 141f and the radiation units 160a to 160c according to the first embodiment. In FIG. 4 and FIG. 5, the microwave radiation mechanisms 143 of the microwave transmission modules 141a to 141f are illustrated as microwave radiation mechanisms 143a to 143f. In the illustration of FIG. 5, in order to clearly illustrate the connection relationship, the microwave radiation mechanisms 143 (143a to 143f) and the distributors 170 (170a to 170f), which are connected to the radiation units 160a to 160c, respectively, are divided into upper and lower parts.

The other end side of the distribution unit 170, which is connected to the radiation units 160, diverges into two by bifurcating once. One end of the distribution unit 170 is connected to the microwave radiation mechanism 143 of the microwave transmission module 141, and the other ends as two branches are connected to two radiation units 160. For example, one end of the distribution unit 170a is connected to the microwave radiation mechanism 143a of the microwave transmission module 141a, and the other ends as two branches are connected to two circumferentially adjacent radiation units 160a. One end of the distribution unit 170b is connected to the microwave radiation mechanism 143b of the microwave transmission module 141b, and the other ends as two branches are connected to two remaining radiation units 160a. One end of the distribution unit 170c is connected to the microwave radiation mechanism 143c of the microwave transmission module 141c, and the other ends as two branches are connected to two circumferentially adjacent radiation units 160b. One end of the distribution unit 170d is connected to the microwave radiation mechanism 143d of the microwave transmission module 141d, and the other ends as two branches are connected to two remaining radiation units 160b. One end of the distribution unit 170e is connected to the microwave radiation mechanism 143e of the microwave transmission module 141e, and the other ends as two branches are connected to two circumferentially adjacent radiation units 160c. One end of the distribution unit 170f is connected to the microwave radiation mechanism 143f of the microwave transmission module 141f, and the other ends as two branches are connected to two remaining radiation units 160c. In the illustration of FIG. 4 and FIG. 5, the branch portions of each of the distributors 170a to 170f reaching the radiation units 160 have a curved shape in the circumferential direction, but may have a straight shape.

The distribution unit 170 distributes and transmits microwaves output from the microwave radiation mechanism 143, to the plurality of radiation units 160. For example, the distribution unit 170a distributes and transmits microwaves output from the microwave radiation mechanism 143a, to the two radiation units 160a. The distribution unit 170b distributes and transmits microwaves output from the microwave radiation mechanism 143b, to the two radiation units 160a. The distribution unit 170c distributes and transmits microwaves output from the microwave radiation mechanism 143c, to the two radiation units 160b. The distribution unit 170d distributes and transmits microwaves output from the microwave radiation mechanisms 143d, to the two radiation units 160b. The distribution unit 170e distributes and transmits microwaves output from the microwave radiation mechanism 143e, to the two radiation units 160c. The distribution unit 170f distributes and transmits microwaves output from the microwave radiation mechanism 143f, to the two radiation units 160c.

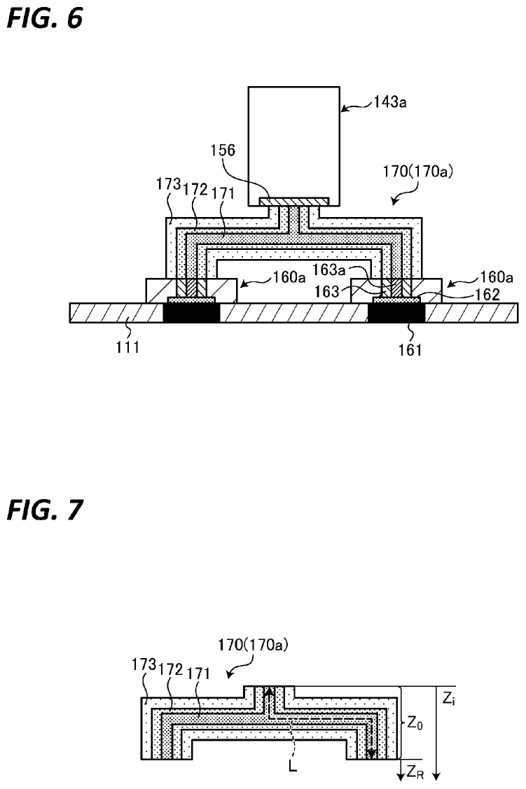

FIG. 6 is a view illustrating a schematic configuration of the distribution unit 170 according to the first embodiment. The distributors 170a to 170f have the same configuration and the radiation units 160a to 160c have the same configuration. Hereinafter, the configurations of the distribution unit 170a and the radiation unit 160a will be described.

The distribution unit 170a is configured as a coaxial line in which the periphery of an inner conductor 171 is covered by a dielectric 172, and the periphery of the dielectric 172 is covered by an outer conductor 173. One end of the distribution unit 170a is connected to the impedance converter 156 of the microwave radiation mechanism 143a, and the other end side is branched and each is connected to the radiation unit 160a.

The radiation unit 160 includes a microwave transmission plate 161, an antenna 162, and a slow-wave material 163.

The microwave transmission plate 161 is fitted into the ceiling wall 111 of the processing container 101. The bottom surface of the microwave transmission plate 161 is exposed to the internal space of the processing container 101. The antenna 162 has a disk shape and is disposed on the top surface of the microwave transmission plate 161.

The slow-wave material 163 is disposed on the top surface of the antenna 162. A conductor 163a is provided while passing through the slow-wave material 163. One end of the conductor 163a is connected to the antenna 162, and the other end of the conductor 163a is connected to the other end of the inner conductor 171 of the distribution unit 170a. The slow-wave material 163 is made of a dielectric. Examples of the dielectric may include quartz, ceramic such as alumina (Al₂O₃), and resins such as polytetrafluoroethylene and polyimide. The slow-wave material 163 may adjust the phase of microwaves depending on its thickness, and may maximize the radiation energy of microwaves. The microwave transmission plate 161 is also made of a dielectric, and has a shape that allows microwaves to be efficiently radiated in a TE mode. Then, the microwaves that have passed through the microwave transmission plate 161 are radiated into the space within the processing container 101 to generate plasma. As for the material for forming the slow-wave material 163 and the microwave transmission plate 161, it is possible to use, for example, quartz or ceramic, fluorine-based resins such as polytetrafluoroethylene resin, and polyimide resins.

Meanwhile, when the distribution unit 170 distributes microwaves to two radiation units 160 as in the embodiment, the transmission line becomes longer due to the distribution unit 170. For short-wavelength electromagnetic waves such as microwaves, in some cases, the length of the transmission line in the portion of the distribution unit 170 may also affect the impedance, thereby affecting impedance matching. For example, in some cases, impedance matching between the input side and the output side may not be achieved, and then reflection or loss of microwaves may occur.

Therefore, in the first embodiment, the distribution unit 170 is configured as follows. FIG. 7 is a view illustrating the characteristic impedance of the distribution unit 170 according to the first embodiment. The line length between the one end of the distribution unit 170 connected to the microwave radiation mechanism 143 and the other end connected to the radiation unit 160 is set as L. The line length L is the length along the center of the inner conductor 171 from one end to the other end. The characteristic impedance of the transmission line in the portion of the distribution unit 170 is set as Z0. The characteristic impedance of the transmission path after the distribution unit 170 is set as Zi. The characteristic impedance of the transmission path after the radiation unit 160 is set as ZR. The characteristic impedances Z0, ZR, and Zi have the relationship of the following equation (1):

$$\\ \begin{matrix}{Z}_{i} = {Z}_{0} \frac{{Z}_{R} + {jZ}_{0} tan \frac{2 π}{λ} L}{{Z}_{0} + {jZ}_{R} tan \frac{2 π}{λ} L} & ( 1 )\end{matrix}$$

Here, λ is the wavelength of microwaves.

In the equation (1), when the line length L=0, λ/2, λ, 3λ/2, . . . , that is, the line length L is an integer multiple of λ/2, Zi=ZR. That is, when the line length L is an integer multiple of λ/2, it is possible to distribute microwaves without affecting impedance.

For example, it is assumed that the frequency of microwaves is 860 MHz. When the dielectric 172 of the distribution unit 170 is made of Teflon (registered trademark), λ/2 becomes 120 mm. When the portion of the dielectric 172 of the distribution unit 170 is made of alumina, λ/2 becomes 56.3 mm. When the portion of the dielectric 172 of the distribution unit 170 is a vacuum space, λ/2 becomes 174 mm.

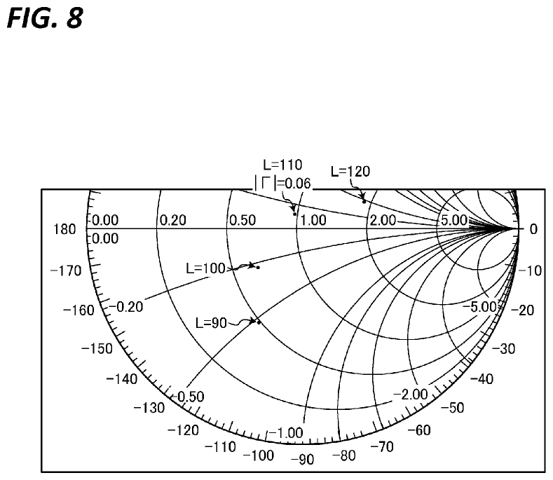

Here, a specific example of the line length L of the distribution unit 170a will be described. The frequency of microwaves is assumed to be 860 MHZ. The dielectric 172 of the distribution unit 170a is made of Teflon (registered trademark). In this case, λ/2 becomes 120 mm. Regarding the distribution unit 170a, impedance matching states were theoretically obtained in cases where the line length L was set as 90 mm, 100 mm, 110 mm, and 120 mm. FIG. 8 is a smith chart illustrating the impedance matching states. In FIG. 8, plotting is made for each of cases where the line length L is set as 90 mm, 100 mm, 110 mm, and 120 mm. Theoretically, the matching comes close to perfection (1.00) when the line length L of the distribution unit 170a is 120 mm. However, in actuality, as illustrated in FIG. 8, when the line length L of the distribution unit 170a is 110 mm, the matching comes close to perfection, and the absolute value of the reflection coefficient Γ is 0.06. The reason for this is thought to be that the characteristic impedance is not constant at the branched portion or the curved portion of the distribution unit 170a. Therefore, the distribution unit 170a is configured such that the line length L falls within a predetermined range from n×λ/2 (n is a natural number) in consideration of the influence of the branched portion or the curved portion. The predetermined range is, for example, a range where the matching comes closer to perfection (1.00), than that when the line length L is set as n×λ/2. For example, in the configuration of the distribution unit 170a, the line length L is 110 mm. The distributors 170b to 170f are also configured to have line lengths L falling within a predetermined range from n×λ/2. Accordingly, the distributors 170a to 170f may distribute microwaves while the influence of the portions of the distributors 170a to 170f on the impedance is suppressed. Therefore, it is possible to suppress impedance matching from not being achieved due to the influence of the distributors 170a to 170f.

When the line length L of each of the distributors 170a to 170f is around n×λ/2, the matching comes close to perfection. Therefore, the predetermined range may be a range of ±λ/8, and the distributors 170a to 170f may be configured to have line lengths L falling within n×λ/2±λ/8. Accordingly, the distributors 170a to 170f may distribute microwaves while the influence of the portions of the distributors 170a to 170f on the impedance is suppressed.

The microwave radiation mechanisms 143a to 143f to which the distributors 170a to 170f are connected, respectively, are configured as slug tuners, and may perform matching adjustment. Therefore, in the configuration of the distributors 170a to 170f, the line length L may be set within a range where impedance matching may be performed by the microwave radiation mechanisms 143a to 143f, from n×λ/2. Accordingly, the distributors 170a to 170f may distribute microwaves while the microwave radiation mechanisms 143a to 143f are performing matching adjustment to achieve the impedance matching.

Next, the operation of the plasma processing apparatus 100 will be described.

In loading the substrate W into the plasma processing apparatus 100, the gate valve 115 is in an open state. The substrate W is loaded into the processing container 101 via the loading/unloading port 114 by a transport mechanism such as a transport arm, and is placed on the stage 102. Under the control of the control unit 200, the plasma processing apparatus 100 performs plasma processing on the substrate W placed on the stage 102. For example, the control unit 200 controls the exhaust device 104 so as to exhaust gases within the processing container 101 to a predetermined degree of vacuum. The control unit 200 controls the gas supply unit 127, so that a processing gas to be used for plasma processing is supplied into the processing container 101 from the gas supply unit 127. Then, the control unit 200 controls the microwave introduction device 105, so that microwaves are generated by the microwave introduction device 105 and are output from each microwave transmission module 141. The microwaves output from each microwave transmission module 141 are radiated into the processing container 101 from the radiation units 160 via each distribution unit 170. Accordingly, plasma is generated within the processing container 101, and plasma processing is performed on the substrate W.

In the plasma processing apparatus 100 according to the first embodiment, each microwave transmission module 141 is connected to two radiation units 160 via the distribution unit 170. Accordingly, in the plasma processing apparatus 100 according to the first embodiment, for example, the number of microwave transmission modules 141 may be reduced by half as compared to when the microwave transmission modules 141 are provided for the radiation units 160, respectively.

In the plasma processing apparatus 100 according to the first embodiment, the ceiling wall 111 of the processing container 101 is provided with the radiation units 160a to 160c which have different diameters from the center, and are spaced apart from each other in the circumferential direction. Four radiation units 160a, four radiation units 160b and four radiation units 160c are disposed on concentric circles from the center of the ceiling wall 111, respectively. The microwave transmission module 141a is connected to two circumferentially adjacent radiation units 160a via the distribution unit 170a. The microwave transmission module 141b is connected to two remaining radiation units 160a via the distribution unit 170b. The microwave transmission module 141c is connected to two circumferentially adjacent radiation units 160b via the distribution unit 170c. The microwave transmission module 141d is connected to two remaining radiation units 160b via the distribution unit 170d. The microwave transmission module 141e is connected to two circumferentially adjacent radiation units 160c via the distribution unit 170e. The microwave transmission module 141f is connected to two remaining radiation units 160c via the distribution unit 170f.

The control unit 200 may individually control the power of microwaves output from the microwave transmission modules 141a to 141f by controlling the amplification sections 142 of the microwave transmission modules 141a to 141f. Accordingly, it is possible to control the power of microwaves radiated from each of the radiation units 160a to 160c, and to control the distribution of plasma generated within the processing container 101. For example, it is possible to control the plasma density near the center of the ceiling wall 111 by controlling the power of microwaves output from the microwave transmission modules 141a and 141b. It is possible to control the plasma density in the annular portion surrounding the center of the ceiling wall 111 by controlling the power of microwaves output from the microwave transmission modules 141c and 141d. It is possible to control the plasma density in the peripheral portion of the ceiling wall 111 by controlling the power of microwaves output from the microwave transmission modules 141e and 141f. It is possible to control a deviation in the plasma distribution by changing the microwave power in the microwave transmission module 141a and the microwave transmission module 141b, in the microwave transmission module 141c and the microwave transmission module 141d, and in the microwave transmission module 141e and the microwave transmission module 141f.

### Second Embodiment

Next, a second embodiment will be described. The configurations of the plasma processing apparatus 100, the microwave introduction device 105, and the microwave radiation mechanism 143 according to the second embodiment are the same as the configurations in the first embodiment illustrated in FIGS. 1 to 3, and thus the descriptions thereof will be omitted.

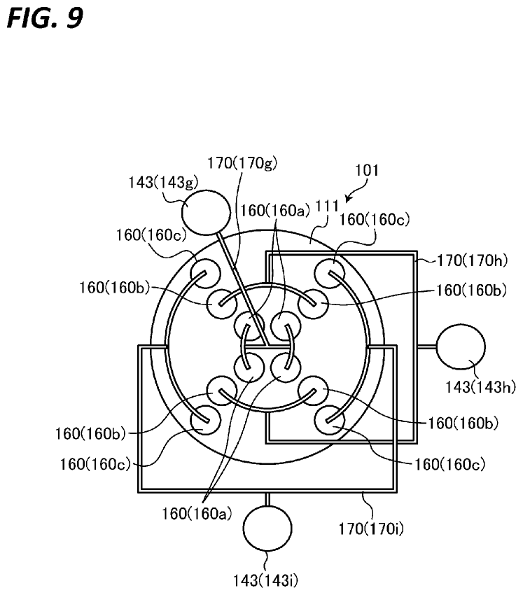

FIG. 9 is a top view illustrating an example of a schematic configuration of the ceiling wall 111 of the processing container 101 according to the second embodiment. The ceiling wall 111 is provided with the radiation units 160a to 160c which have three diameters from the center side of the ceiling wall 111. Four radiation units 160a, four radiation units 160b and four radiation units 160c are arranged at equal intervals on concentric circles from the center of the ceiling wall 111, respectively.

In the second embodiment, three microwave transmission modules 141 (141g to 141i) are provided in the microwave radiation unit 140. Each of the microwave transmission modules 141g to 141i is connected to four radiation units 160 via the distribution unit 170 (170g to 170i).

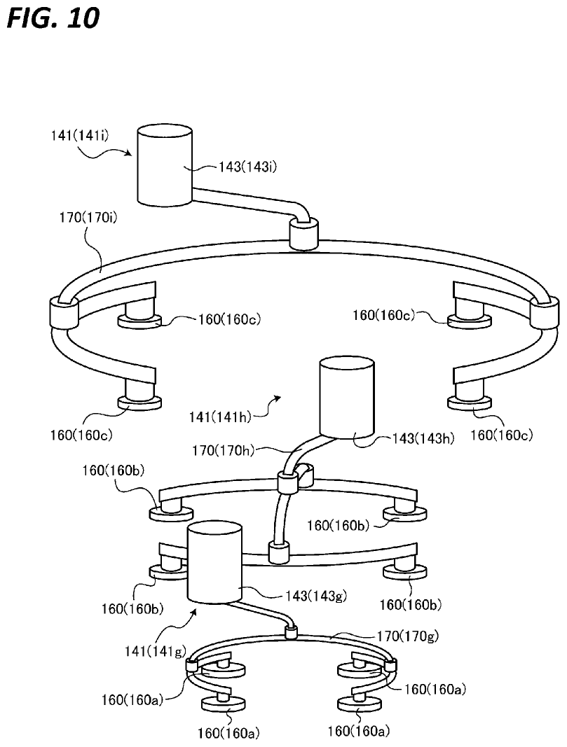

FIG. 9 and FIG. 10 described above illustrate the connection relationship between the microwave transmission modules 141g to 141i and the radiation units 160a to 160c. FIG. 10 is a view illustrating the connection relationship between the microwave transmission modules 141g to 141i and the radiation units 160a to 160c according to the second embodiment. In FIG. 9 and FIG. 10, the microwave radiation mechanisms 143 of the microwave transmission modules 141g to 141i are illustrated as microwave radiation mechanisms 143g to 143i. In the illustration of FIG. 10, in order to clearly illustrate the connection relationship, the microwave radiation mechanisms 143 (143g to 143i) and the distributors 170 (170g to 170i), which are connected to the radiation units 160a to 160c, respectively, are divided into upper and lower parts.

The other end side of the distribution unit 170, which is connected to the radiation units 160, diverges into four by bifurcating twice. One end of the distribution unit 170 is connected to the microwave radiation mechanism 143 of the microwave transmission module 141, and the other ends as four branches are connected to four radiation units 160. For example, one end of the distribution unit 170g is connected to the microwave radiation mechanism 143g of the microwave transmission module 141g, and the other ends as four branches are connected to four radiation units 160a. One end of the distribution unit 170h is connected to the microwave radiation mechanism 143h of the microwave transmission module 141h, and the other ends as four branches are connected to four radiation units 160b. One end of the distribution unit 170i is connected to the microwave radiation mechanism 143i of the microwave transmission module 141i, and the other ends as four branches are connected to four radiation units 160c.

The distribution unit 170 distributes and transmits microwaves output from the microwave radiation mechanism 143, to the plurality of radiation units 160. For example, the distribution unit 170g distributes and transmits microwaves output from the microwave radiation mechanism 143g, to the four radiation units 160a. The distribution unit 170h distributes and transmits microwaves output from the microwave radiation mechanism 143h, to the four radiation units 160b. The distribution unit 170i distributes and transmits microwaves output from the microwave radiation mechanism 143i, to the four radiation units 160c.

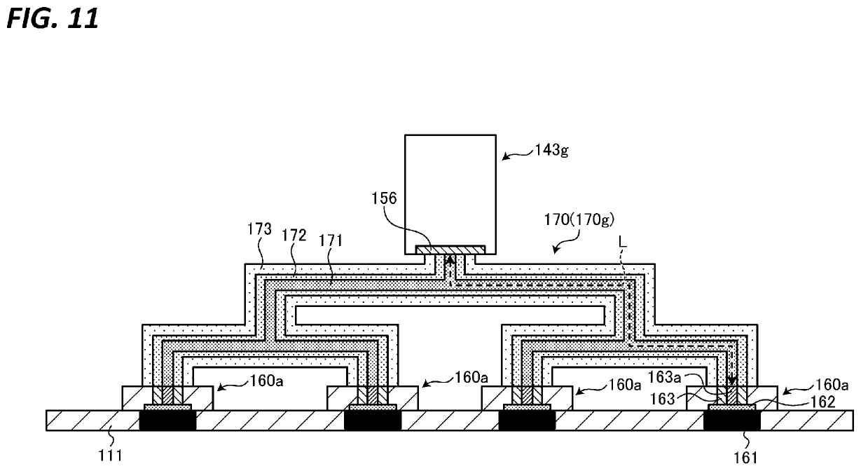

FIG. 11 is a view illustrating a schematic configuration of the distribution unit 170 according to the second embodiment. The distributors 170g to 170i have the same configuration and the radiation units 160a to 160c have the same configuration. Hereinafter, the configurations of the distribution unit 170g and the radiation unit 160a will be described.

One end of the distribution unit 170g is connected to the impedance converter 156 of the microwave radiation mechanism 143g, and the other end side is bifurcated twice and each is connected to the radiation unit 160a.

On the distribution unit 170g, a line length L is illustrated between one end connected to the microwave radiation mechanism 143g and the other end connected to the radiation unit 160a. The line length L is the length along the center of the inner conductor 171 from one end to the other end.

The distribution unit 170g is configured such that the line length L falls within a predetermined range from n×λ/2 in consideration of the influence of the branched portion or the curved portion. The distributors 170h and 170i are also configured to have line lengths L falling within a predetermined range from n×λ/2. Accordingly, the distributors 170g to 170i may distribute microwaves while the influence of the portions of the distributors 170g to 170i on the impedance is suppressed. Therefore, it is possible to suppress the distributors 170g to 170i from affecting impedance matching and making it impossible to achieve the impedance matching.

When the line length L of each of the distributors 170g to 170i is around n×λ/2, the matching comes close to perfection. Therefore, the predetermined range may be a range of ±λ/8, and the distributors 170g to 170i may be configured to have line lengths L falling within n×λ/2±λ/8. In the configuration of the distributors 170g to 170i, the line length L may be set within a range where impedance matching may be performed by the microwave radiation mechanisms 143g to 143i, from n×λ/2. Accordingly, the distributors 170g to 170i may distribute microwaves while the influence of the portions of the distributors 170g to 170i on the impedance is suppressed.

Next, the operation of the plasma processing apparatus 100 will be described.

The substrate W as a processing target is loaded into the processing container 101 via the loading/unloading port 114 and is placed on the stage 102. Under the control of the control unit 200, the plasma processing apparatus 100 performs plasma processing on the substrate W placed on the stage 102. For example, the control unit 200 controls the exhaust device 104 so as to exhaust gases within the processing container 101 to a predetermined degree of vacuum. The control unit 200 controls the gas supply unit 127, so that a processing gas to be used for plasma processing is supplied into the processing container 101 from the gas supply unit 127. Then, the control unit 200 controls the microwave introduction device 105, so that microwaves are generated by the microwave introduction device 105 and are output from each microwave transmission module 141. The microwaves output from each microwave transmission module 141 are radiated into the processing container 101 from the radiation units 160 via each distribution unit 170. Accordingly, plasma is generated within the processing container 101, and plasma processing is performed on the substrate W.

In the plasma processing apparatus 100 according to the second embodiment, each microwave transmission module 141 is connected to four radiation units 160 via the distribution unit 170. Accordingly, in the plasma processing apparatus 100 according to the second embodiment, for example, the number of microwave transmission modules 141 may be reduced to ¼ as compared to when the microwave transmission modules 141 are provided for the radiation units 160, respectively.

In the plasma processing apparatus 100 according to the second embodiment, the ceiling wall 111 of the processing container 101 is provided with the radiation units 160a to 160c which have different diameters from the center, and are spaced apart from each other in the circumferential direction. Four radiation units 160a, four radiation units 160b, and four radiation units 160c are disposed on concentric circles from the center of the ceiling wall 111, respectively. The microwave transmission module 141g is connected to four radiation units 160a via the distribution unit 170g. The microwave transmission module 141h is connected to four radiation units 160b via the distribution unit 170h. The microwave transmission module 141i is connected to four radiation units 160c via the distribution unit 170i.

The control unit 200 may individually control the power of microwaves output from the microwave transmission modules 141g to 141i by controlling the amplification sections 142 of the microwave transmission modules 141g to 141i. Accordingly, it is possible to control the power of microwaves radiated from each of the radiation units 160a to 160c, and to control the distribution of plasma. For example, it is possible to control the plasma density near the center of the ceiling wall 111 by controlling the power of microwaves output from the microwave transmission module 141g. It is possible to control the plasma density in the annular portion surrounding the center of the ceiling wall 111 by controlling the power of microwaves output from the microwave transmission module 141h. It is possible to control the plasma density in the peripheral portion of the ceiling wall 111 by controlling the power of microwaves output from the microwave transmission module 141i.

In the first and second embodiments described above, descriptions have been made using an example of a case where the microwave transmission module 141 is connected to two or four radiation units 160 via the distribution unit 170. However, the disclosed technology is not limited to this. More radiation units 160 may be connected to the microwave transmission module 141 via the distribution unit 170. When the number of times of bifurcating is increased by one at the other end side of the distribution unit 170, the number of the radiation units 160 to be connected may be doubled. In this case as well, in the configuration of the distribution unit 170, the line length L from one end connected to the microwave radiation mechanism 143g to the other end connected to the radiation unit 160 may fall within a predetermined range from n×λ/2. Then, it is possible to distribute microwaves while suppressing the influence of the portion of the distribution unit 170 on the impedance.

In the first and second embodiments described above, descriptions have been made using an example of a case where the other end side of the distribution unit 170 diverges into two each time, and thus the number of the other ends is increased. However, the disclosed technology is not limited to this. The other end side of the distribution unit 170 may diverge into three or more each time. In this case, in the configuration of the distribution unit 170, each line length L from one end connected to the microwave radiation mechanism 143g to the other end connected to the radiation unit 160 may fall within a predetermined range from n×λ/2. Then, it is possible to distribute microwaves while suppressing the influence of the portion of the distribution unit 170 on the impedance.

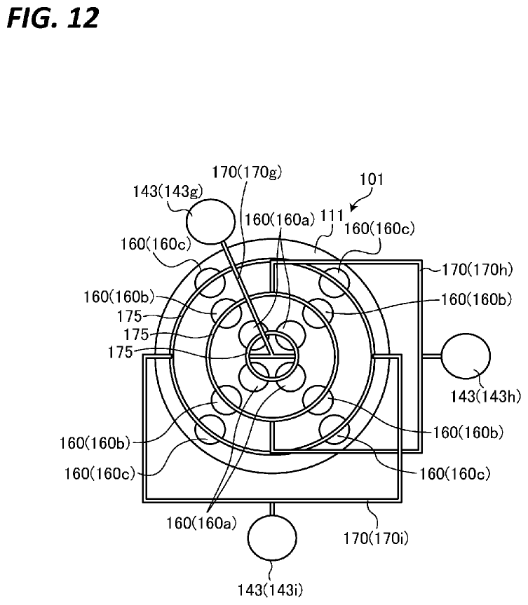

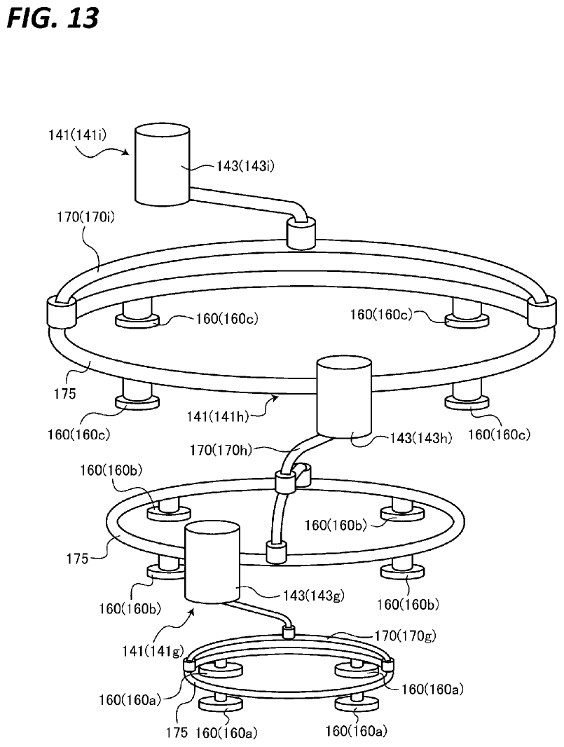

In the first and second embodiments described above, descriptions have been made using an example of a case where the other end side of the distribution unit 170 diverges into two, and the transmission line is divided in a tree form. However, the disclosed technology is not limited to this. A ring-shaped transmission line that transmits microwaves may be formed in a part of the distribution unit 170. FIGS. 12 and 13 are views illustrating an example of the distribution unit 170 having a ring-shaped transmission line according to the second embodiment. FIGS. 12 and 13 illustrate a case where ring-shaped transmission lines 175 are provided in the distributors 170g to 170i according to the second embodiment. In the illustration of FIG. 13, in order to clearly illustrate the connection relationship, the microwave radiation mechanisms 143 (143g to 143i) and the distributors 170 (170g to 170i), which are connected to the radiation units 160a to 160c, respectively, are divided into upper and lower parts. From one end of each of the distributors 170g to 170i connected to the microwave radiation mechanisms 143, two branches diverge once, and each is connected to the ring-shaped transmission line 175. Then, four other ends of each of the distributors 170g to 170i, which diverge from the ring-shaped transmission line 175, are connected to four radiation units 160. Since the ring-shaped transmission line 175 is provided in the distribution unit 170, the branched microwaves are transmitted to the ring-shaped transmission line 175. Accordingly, even when a deviation occurs in the microwave power due to branching, the deviation in the microwave power may be suppressed through the ring-shaped transmission line 175. Thus, the distribution unit 170 may transmit microwaves with equal power to the four radiation units 160. In this case, in the configuration of the distribution unit 170, each shortest line length L from one end connected to the microwave radiation mechanism 143 to the other end connected to the radiation unit 160 falls within a predetermined range from n×λ/2. Accordingly, it is possible to distribute microwaves while suppressing the influence of the portion of the distribution unit 170 on the impedance.

In the first and second embodiments described above, descriptions have been made using an example of a case where the distribution unit 170 is configured as a coaxial line. However, the disclosed technology is not limited to this. The distribution unit 170 may have any configuration as long as microwaves may be distributed and transmitted to the plurality of radiation units 160. For example, the distribution unit 170 may be configured with a coaxial line and a strip line. The strip line may be manufactured using, for example, a printed circuit board. By using the strip line for the distribution unit 170, the distribution unit 170 may be easily manufactured.

### Effects

So far, the embodiments have been described. As described above, the plasma processing apparatus 100 according to the embodiments includes the processing container 101 (chamber), the microwave introduction device 105 (microwave source), and the distribution unit 170. The processing container 101 is configured such that within the processing container 101, the substrate W may be disposed, and the radiation units 160 that radiate microwaves are arranged while facing the substrate W. The microwave introduction device 105 is configured to output microwaves. The distribution unit 170 has one end connected to the microwave introduction device 105 and the other end connected to the radiation units 160 through branching, and is configured to distribute and transmit the microwaves output from the microwave introduction device 105 to the radiation units 160, in which when a wavelength of the microwaves is λ, a line length L from one end to the other end falls within a predetermined range from n×λ/2 (n is a natural number). Accordingly, the plasma processing apparatus 100 may distribute microwaves while suppressing the influence of the impedance in the portion of the distribution unit 170, on the impedance.

The microwave introduction device 105 includes the microwave radiation mechanism 143 (a matching unit) that performs matching with load impedance, in the microwave transmission module 141 (a microwave transmitter) that outputs the microwaves, in which the microwave radiation mechanism 143 (the matching unit) is connected to one end of the distribution unit 170. The distribution unit 170 is configured such that the line length L falls within a range where impedance matching may be performed by the microwave radiation mechanism 143, from n×λ/2. Accordingly, the plasma processing apparatus 100 may distribute microwaves while suppressing the influence in the portion of the distribution unit 170 on impedance.

The distribution unit 170 is configured such that the line length L falls within n×λ/2±λ/8. Accordingly, the plasma processing apparatus 100 may distribute microwaves while suppressing the influence in the portion of the distribution unit 170 on impedance.

The distribution unit 170 is configured such that a ring-shaped transmission line that transmits the microwaves is formed in a part of the distribution unit 170, and a shortest line length L from one end to the other end falls within a predetermined range from n×λ/2. Accordingly, the plasma processing apparatus 100 may distribute microwaves while achieving impedance matching.

The distribution unit 170 is configured such that the other end is bifurcated one or more times, and is connected to the radiation units 160. Accordingly, in the plasma processing apparatus 100, the number of the microwave transmission modules 141 may be reduced as compared to when the microwave transmission modules 141 are provided for the radiation units 160, respectively.

The distribution unit 170 is configured with a coaxial line and a strip line. Accordingly, the distribution unit 170 may be easily manufactured.

The processing container 101 is configured such that the radiation units 160 are provided on a wall surface (the ceiling wall 111) facing the substrate W so as to surround a position corresponding to a center of the substrate W. The microwave transmission modules 141 (microwave transmitters) that output the microwaves are provided in the microwave introduction device 105, and the number of the microwave transmission modules 141 is half or less than half the number of the radiation units 160. The distributors 170 are provided corresponding to the number of the microwave transmission modules 141, in which one end of each of the distributors 170 is connected to the microwave transmission module 141 so as to connect each of the microwave transmission modules 141 to the two or more radiation units 160. Accordingly, the plasma processing apparatus 100 may generate plasma over a wide range from the center of the substrate W by the microwaves radiated from the radiation units 160, and may perform plasma processing on the entire surface of the substrate W. In the plasma processing apparatus 100, for example, the number of the microwave transmission modules 141 may be reduced as compared to when the microwave transmission modules 141 are provided for the radiation units 160, respectively.

The processing container 101 is configured such that the radiation units 160 are provided on the wall surface (the ceiling wall 111), which have different diameters from the position corresponding to the center of the substrate W, and are spaced apart from each other in a circumferential direction. The number of the microwave transmission modules 141 provided for each of the diameters is half the number of the radiation units 160 provided in the circumferential direction for the diameter. For each of the diameters, the distributors 170 are provided corresponding to the number of the microwave transmission modules 141 for the diameter, so as to connect the microwave transmission module 141 for the diameter to the two or more circumferentially adjacent radiation units 160 for the diameter. Accordingly, the plasma processing apparatus 100 may generate plasma over a wide range from the position corresponding to the center of the substrate W by the microwaves radiated from the radiation units 160, and may perform plasma processing on the entire surface of the substrate W. In the plasma processing apparatus 100, for example, the number of the microwave transmission modules 141 may be reduced as compared to when the microwave transmission modules 141 are provided for the radiation units 160, respectively.

The plasma processing apparatus 100 according to the second embodiment further includes the control unit 200. The control unit 200 is configured such that for each of the diameters, power of the microwaves output by the microwave transmission modules 141 for the diameter is controlled. Accordingly, the plasma processing apparatus 100 may control the distribution of plasma generated in the processing container 101.

One microwave transmission module 141 is provided for each of the diameters. One distribution unit 170 is provided for each of the diameters, so as to connect the microwave transmission module 141 for the diameter to the radiation units 160 for the diameter. Accordingly, in the plasma processing apparatus 100, the number of the microwave transmission modules 141 may be reduced and the plasma distribution in the radial direction from the center of the substrate W may be controlled.

The processing container 101 is configured such that four radiation units 160 are provided on the wall surface (the ceiling wall 111), at equal intervals in the circumferential direction, for each of the different diameters from the position corresponding to the center of the substrate W. Accordingly, in the plasma processing apparatus 100, the number of the microwave transmission modules 141 may be reduced and uniform plasma may be generated in the circumferential direction.

Regarding the above embodiments, the following additional notes are further disclosed.

### Appendix 1

A plasma processing apparatus including:
a chamber configured to place a substrate therein, and including a plurality of microwave radiators that is arranged while facing the substrate;
a microwave source configured to output microwaves; and
a distributor having one end connected to the microwave source and an other end branched and connected to the plurality of microwave radiators, and configured to distribute and transmit the microwaves output from the microwave source to the plurality of microwave radiators, wherein when a wavelength of the microwaves is λ, a line length from the one end to the other end falls within a predetermined range beginning from n×λ/2 (n is a natural number).

### Appendix 2

The plasma processing apparatus described in Appendix 1, wherein the microwave source includes a matching box that performs matching with load impedance, in a microwave transmitter that outputs the microwaves, the matching box being connected to the one end of the distributor, and
the distributor is configured such that the line length falls within a range where impedance is matched by the matching box, from n×λ/2.

### Appendix 3

The plasma processing apparatus described in Appendix 1, wherein the distributor is configured such that the line length falls within n×λ/2±λ/8.

### Appendix 4

The plasma processing apparatus described in any one of Appendixes 1 to 3, wherein the distributor is configured such that a ring-shaped transmission line that transmits the microwaves is formed in a portion of the distributor, and a shortest line length from the one end to the other end falls within a predetermined range beginning from n×λ/2.

### Appendix 5

The plasma processing apparatus described in any one of Appendixes 1 to 4, wherein the distributor is configured such that the other end is bifurcated one or more times, and is connected to the plurality of microwave radiators.

### Appendix 6

The plasma processing apparatus described in any one of Appendixes 1 to 5, wherein the distributor is configured with a coaxial line and a strip line.

### Appendix 7

The plasma processing apparatus described in any one of Appendixes 1 to 6, wherein the chamber is configured such that the plurality of microwave radiators are provided on a wall surface facing the substrate to surround a position corresponding to a center of the substrate,
the microwave source is provided with a number of microwave transmitters that output the microwaves, the number of which is half or less than half a number of the plurality of microwave radiators, and
a plurality of distributors are provided corresponding to the number of the microwave transmitters, each of the plurality of distributors having one end connected to the microwave transmitter and connecting each of the microwave transmitters to two or more microwave radiators.

### Appendix 8

The plasma processing apparatus described in Appendix 7, wherein the chamber is configured such that the plurality of microwave radiators are provided on the wall surface with a plurality of diameters differing from a position corresponding to the center of the substrate and are spaced apart from each other in a circumferential direction,
the number of the microwave transmitters provided for each of the plurality of diameters is half or less than half the number of the plurality of microwave radiators provided in the circumferential direction of the plurality of diameters, and
the plurality of distributors are provided for each of the plurality of diameters with the number of the microwave transmitters of the diameter, and configured to connect the microwave transmitter of the diameter to two or more microwave radiators adjacent in the circumferential direction of the diameter.

### Appendix 9

The plasma processing apparatus described in Appendix 8, further including a controller configured to control, for each of the plurality of diameters, power of the microwaves output by the microwave transmitter of the diameter.

### Appendix 10

The plasma processing apparatus described in Appendix 8 or 9, wherein one microwave transmitter is provided for each of the plurality of diameters, and
one distributor is provided for each of the plurality of diameters, thereby connecting the microwave transmitter of the diameter to the microwave radiator of the diameter.

### Appendix 11

The plasma processing apparatus described in any one of Appendixes 8 to 10, wherein the chamber is configured such that the wall surface is provided with four microwave radiators for each of a plurality of diameters differing from the position corresponding to the center of the substrate, at equal intervals in the circumferential direction.

According to the present disclosure, it is possible to distribute microwaves while suppressing the influence in the portion of the distributor, on the impedance.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a chamber configured to place a substrate therein, and including a plurality of microwave radiators that is arranged while facing the substrate;
a microwave source configured to output microwaves; and
a distributor having one end connected to the microwave source and an other end branched and connected to the plurality of microwave radiators, and configured to distribute and transmit the microwaves output from the microwave source to the plurality of microwave radiators, wherein when a wavelength of the microwaves is λ, a line length from the one end to the other end falls within a predetermined range beginning from n×λ/2 (n is a natural number).

2. The plasma processing apparatus according to claim 1, wherein the microwave source includes a matching box that performs matching with load impedance, in a microwave transmitter that outputs the microwaves, the matching box being connected to the one end of the distributor, and
the distributor is configured such that the line length falls within a range where impedance is matched by the matching box, from n×λ/2.

3. The plasma processing apparatus according to claim 1, wherein the distributor is configured such that the line length falls within n×λ/2±λ/8.

4. The plasma processing apparatus according to claim 1, wherein the distributor is configured such that a ring-shaped transmission line that transmits the microwaves is formed in a portion of the distributor, and a shortest line length from the one end to the other end falls within a predetermined range beginning from n×λ/2.

5. The plasma processing apparatus according to claim 1, wherein the distributor is configured such that the other end is bifurcated one or more times, and is connected to the plurality of microwave radiators.

6. The plasma processing apparatus according to claim 1, wherein the distributor is configured with a coaxial line and a strip line.

7. The plasma processing apparatus according to claim 1, wherein the chamber is configured such that the plurality of microwave radiators are provided on a wall surface facing the substrate to surround a position corresponding to a center of the substrate,
the microwave source is provided with a number of microwave transmitters that output the microwaves, the number of which is half or less than half a number of the plurality of microwave radiators, and
a plurality of distributors are provided corresponding to the number of the microwave transmitters, each of the plurality of distributors having one end connected to the microwave transmitter and connecting each of the microwave transmitters to two or more microwave radiators.

8. The plasma processing apparatus according to claim 7, wherein the chamber is configured such that the plurality of microwave radiators are provided on the wall surface with a plurality of diameters differing from a position corresponding to the center of the substrate and are spaced apart from each other in a circumferential direction,
the number of the microwave transmitters provided for each of the plurality of diameters is half or less than half the number of the plurality of microwave radiators provided in the circumferential direction of the plurality of diameters, and
the plurality of distributors are provided for each of the plurality of diameters with the number of the microwave transmitters of the diameter, and configured to connect the microwave transmitter of the diameter to two or more microwave radiators adjacent in the circumferential direction of the diameter.

9. The plasma processing apparatus according to claim 8, further comprising a controller configured to control, for each of the plurality of diameters, power of the microwaves output by the microwave transmitter of the diameter.

10. The plasma processing apparatus according to claim 8, wherein one microwave transmitter is provided for each of the plurality of diameters, and
one distributor is provided for each of the plurality of diameters, thereby connecting the microwave transmitter of the diameter to the microwave radiator of the diameter.

11. The plasma processing apparatus according to claim 8, wherein the chamber is configured such that the wall surface is provided with four microwave radiators for each of a plurality of diameters differing from the position corresponding to the center of the substrate, at equal intervals in the circumferential direction.
